(19) United States
(12) Patent Application Publication
(10) Pub. No.: US 2018/0016703 A1
(43) Pub. Date: Jan. 18, 2018

(54) METHOD FOR PRODUCING CRYSTAL

(71) Applicant: KYOCERA Corporation, Kyoto-shi, Kyoto (JP)

(72) Inventors: Chiaki DOMOTO, Soraku-gun (JP); Katsuaki MASAKI, Kyoto-shi (JP); Yutaka KUBA, Soraku-gun (JP)

(21) Appl. No.: 15/554,819

(22) PCT Filed: Jan. 26, 2016
(86) PCT No.: PCT/JP2016/052080

§ 371 Date: Aug. 31, 2017

(30) Foreign Application Priority Data
Mar. 6, 2015 (JP) 2015-044259

(51) Int. Cl. C30B 15/14; C30B 29/36; C30B 19/04

(52) U.S. Cl. CPC C30B 15/14; C30B 19/04; C30B 29/36

(57) ABSTRACT

A method for producing a crystal of silicon carbide includes a preparation step, a contact step, a start step, a first growth step, a cooling step, and a second growth step.

### TECHNICAL FIELD

The present invention relates to a method for producing a crystal of silicon carbide.

### BACKGROUND ART

As described in, for example, Japanese Unexamined Patent Application Publication No. 2010-184849, a method is known in which silicon carbide (SiC) crystal is grown from the lower surface of a silicon carbide seed crystal by a solution method using a solution containing carbon (C) and silicon (Si).

### SUMMARY OF INVENTION

The method for producing a crystal disclosed herein, which is a method for producing a crystal of silicon carbide, includes a preparation step, a contact step, a start step, a first growth step, a cooling step, and a second growth step. In the preparation step, a solution of carbon dissolved in a silicon solvent, and a silicon carbide seed crystal are prepared. In the contact step, the lower surface of the seed crystal is brought into contact with the solution. In the start step, a crystal is started to grow from the lower surface of the seed crystal by heating the solution to a temperature in a first temperature range. Subsequent to the start step, the crystal is grown in the first growth step by pulling up the seed crystal while the solution is further heated from the temperature in the first temperature range to a temperature in a second temperature range. In the cooling step, the solution is cooled from the temperature in the second temperature range to a temperature in the first temperature range. After the cooling step, the crystal is further grown in the second growth step by pulling up the seed crystal while the solution is heated from the temperature in the first temperature range to a temperature in the second temperature range.

### BRIEF DESCRIPTION OF DRAWINGS

FIG. 1 is a schematic sectional view of a crystal producing apparatus used in the crystal producing method of the present disclosure.

FIG. 2 is a graph illustrating the general relationship between the elapsed time and the solution temperature in the crystal producing method of the present disclosure.

### DESCRIPTION OF EMBODIMENTS

### Crystal Producing Apparatus

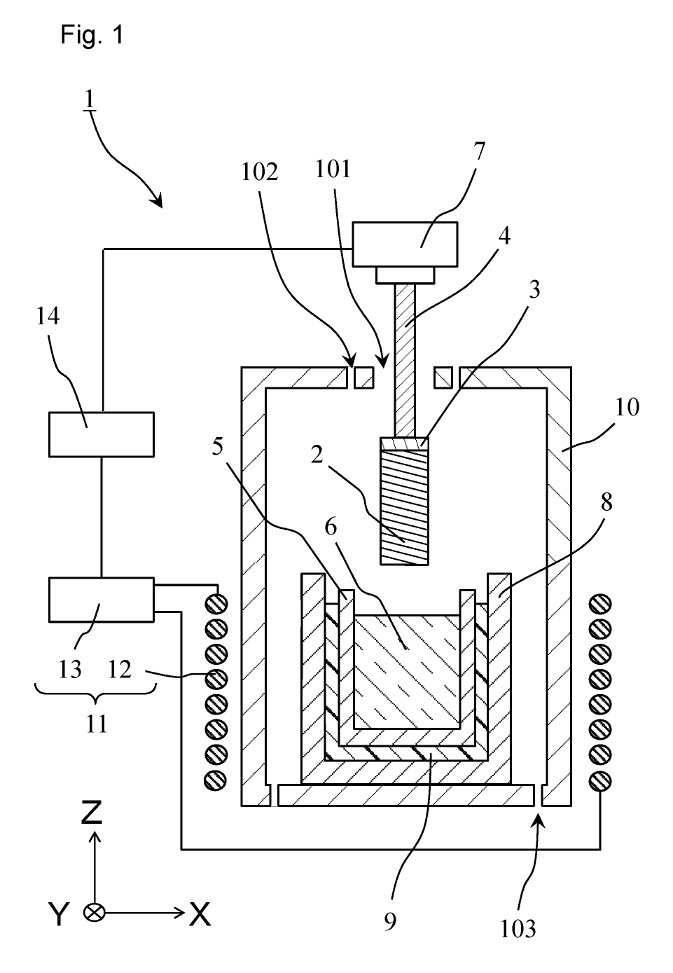

A crystal producing apparatus used in the crystal producing method of the present disclosure will now be described with reference to FIG. 1. FIG. 1 schematically illustrates an exemplary crystal producing apparatus. The present invention is not limited to the embodiment disclosed herein (present embodiment), and various modifications and improvements may be made without departing from the spirit and scope of the invention.

A crystal producing apparatus 1 is intended to produce a crystal 2 of silicon carbide used in semiconductor components or the like. The crystal producing apparatus 1 allows a crystal 2 to grow from the lower surface of a seed crystal 3, thus producing the crystal 2. As illustrated in FIG. 1, the crystal producing apparatus 1 includes a holding member 4 and a crucible 5. The seed crystal 3 is fixed to the holding member 4, and the crucible 5 contains a solution 6. The crystal producing apparatus 1 brings the lower surface of the seed crystal 3 into contact with the solution 6 and thus grows the crystal 2 from the lower surface of the seed crystal 3.

The crystal 2 may be, for example, processed into wafer that will be further processed into a part of a semiconductor component through a manufacturing process of the semiconductor component. The crystal 2 is a lump or mass of silicon carbide crystals grown from the lower surface of the seed crystal 3. The crystal 2 may be, for example, plate-like or columnar. The crystal 2 may have, for example, a circular or a polygonal shape in plan view. The crystal 2 may be a monocrystalline silicon carbide crystal. The crystal 2 has a diameter or a width in the range of, for example, 25 mm to 200 mm. The crystal 2 has a height in the range of, for example, 30 mm to 300 mm. The phrase “a diameter or a width” refers to the length of a straight line passing through the center in plan view of the crystal 2 and reaching the ends in plan view of the crystal. The height of the crystal 2 refers to the distance from the lower surface of the crystal 2 to the upper surface thereof (lower surface of the seed crystal 3).

The seed crystal 3 acts as the seed of the crystal 2. In other words, the seed crystal 3 provides a surface from which the crystal 2 grows. The seed crystal 3 may be, for example, in a plate-like shape. The seed crystal 3 may have, for example, a circular or a polygonal shape in plan view. The seed crystal 3 may be a crystal of the same material as the crystal 2. Since a crystal 2 of silicon carbide is produced in the present embodiment, the seed crystal 3 is a silicon carbide crystal. The seed crystal 3 may be, for example, monocrystalline or polycrystalline. In the present embodiment, the seed crystal 3 is monocrystalline.

The seed crystal 3 is fixed to the lower surface of the holding member 4. The seed crystal 3 may be fixed to the holding member 4 with, for example, an adhesive containing carbon.

The holding member 4 can hold the seed crystal 3. Also, the holding member 4 carries the seed crystal 3 into and out of the solution 6. In other words, the holding member 4 can bring the seed crystal 3 into contact with the solution 6 and move the crystal 2 off the solution 6.

The holding member 4 is fixed to a moving mechanism of a moving device 7, as illustrated in FIG. 1. The moving device 7 vertically moves the holding member 4 by using, for example, a motor. Consequently, the seed crystal 3 is vertically moved with the movement of the holding member 4 caused by the moving device 7.

The holding member 4 may be, for example, columnar. The holding member 4 may be made of, for example, polycrystalline carbon or fired carbon. The holding member 4 may be fixed to the moving device 7 and rotatable on an axis extending in a vertical direction through the center in plan view of the holding member 4. In other words, the holding member 4 may rotate on its own axis.

The solution 6, which is accommodated (contained) in the crucible 5, supplies the raw material of the crystal 2 to the seed crystal 3, thus enabling the crystal 2 to grow. The solution 6 contains the same constituents as the crystal 2. More specifically, since the crystal 2 is a silicon carbide crystal, the solution 6 contains carbon and silicon. The solution 6 in the present embodiment is prepared by dissolving carbon as a solute in a solvent of silicon (silicon solvent). From the viewpoint of increasing the solubility of carbon and other reasons, the solution 6 may contain one or more metals, such as neodymium (Nd), aluminum (Al), tantalum (Ta), scandium (Sc), chromium (Cr), zirconium (Zr), nickel (Ni), or yttrium (Y), as an additive.

The crucible 5 can accommodate the solution 6. The crucible 5 allows the raw material of the crystal 2 to be melted therein. The crucible 5 may be made of, for example, a material containing carbon. The crucible 5 used in the present embodiment is made of, for example, graphite. In the present embodiment, silicon is melted within the crucible 5, and a part (carbon) of the crucible 5 is dissolved in the melted silicon to yield the solution 6. The crucible 5 is a member, for example, in a recessed shape whose top is open to receive the solution 6.

In the present embodiment, the crystal 2 of silicon carbide is grown by a solution method. In the solution method, while the solution 6 is kept in a thermodynamically metastable state in the vicinity of the seed crystal 3, the crystal 2 is grown from the lower surface of the seed crystal 3 under the condition controlled so that the crystal 2 is precipitated at a higher rate than the rate at which it is dissolved. In the solution 6, carbon (solute) is dissolved in silicon (solvent). The higher the temperature of the solvent, the higher the solubility of carbon. If the solution 6 heated to a high temperature is cooled by contact with the seed crystal 3, the dissolved carbon precipitates, and the solution 6 is supersaturated with the carbon, thus coming into a metastable state locally in the vicinity of the seed crystal 3. Then, the crystal 2 precipitates at the lower surface of the seed crystal 3 with the solution 6 coming into a stable state (thermodynamically equilibrium state). Consequently, the crystal 2 is grown from the lower surface of the seed crystal 3.

The crucible 5 is disposed within a crucible container 8. The crucible container 8 can hold the crucible 5. A heat insulation material 9 is disposed between the crucible container 8 and the crucible 5. The crucible 5 is surrounded by the heat insulation material 9. The heat insulation material 9 suppresses heat dissipation from the crucible 5 and helps the inside of the crucible 5 have a nearly uniform temperature distribution. The crucible 5 may be disposed within the crucible container 8 and rotatable on an axis extending in a vertical direction through the center of the bottom in plan view of the crucible 5. In other words, the crucible 5 may rotate on its own axis.

The crucible container 8 is disposed within a chamber 10. The chamber 10 can separate the space for growing the crystal 2 from the external atmosphere. The presence of the chamber 10 can reduce the contamination of the crystal 2 with unnecessary impurities. The chamber 10 may be filled with, for example, an inert gas. Thus, the inside of the chamber 10 can be isolated from the outside. The crucible container 8 may be supported on the bottom of the chamber 10. The bottom of the crucible container 8 may be supported by a support shaft extending downward therefrom through the bottom of the chamber 10.

The chamber 10 has a through hole 101 through which the holding member 4 passes, a gas supply port 102 through which a gas is introduced into the chamber 10, and an exhaust port 103 through which the gas is discharged from the chamber 10. Furthermore, the crystal producing apparatus 1 includes a gas supply portion capable of supplying a gas into the chamber 10. The gas in the crystal producing apparatus 1 is introduced into the chamber 10 through the supply port 102 from the gas supply portion and is discharged through the exhaust port 103.

The chamber 10 may be, for example, in a hollow cylindrical shape. The chamber 10 has a circular bottom with a diameter, for example, in the range of 150 mm to 1000 mm, and the height of the chamber is, for example, in the range of 500 mm to 2000 mm. The chamber 10 may be made of, for example, stainless steel or an insulating material, such as quartz. The inert gas introduced into the chamber 10 may be argon (Ar), helium (He), or the like.

The crucible 5 is heated with a heating device 11. The heating device 11 used in the present embodiment includes a coil 12 and an alternating-current power supply 13 and can heat the crucible 5 by, for example, induction heating using electromagnetic waves. The heating device 11 may operate, for example, to conduct heat generated from a heating resistor of carbon or the like or may operate in any other manner. If the heating device operates to conduct heat, a heating resistor may be disposed (between the crucible 5 and the heat insulation material 9).

The coil 12 is made of a conductor and surrounds the periphery of the crucible 5. In the present embodiment, the coil 12 is disposed around the chamber 10 in such a manner that the coil 12 cylindrically surrounds the crucible 5. The heating device 11 including the coil 12 has a hollow cylindrical heating region defined by the coil 12. Although the coil 12 is disposed around the chamber 10 in the present embodiment, the coil 12 may be disposed within the chamber 10.

The alternating-current power supply 13 can apply an alternating current to the coil 12. An electric field is generated by applying the current to the coil 12, and thus an induced current is generated at the crucible container 8 in the electric field. The Joule heat of the induced current heats the crucible container 8. The heat of the crucible container 8 is conducted to the crucible 5 through the heat insulation material 9, thus heating the crucible 5. The alternating current may be adjusted to a frequency at which the induced current flows easily to the crucible container 8. This can reduce the heating time for heating the inside of the crucible 5 to a predetermined temperature and increase power efficiency.

In the present embodiment, the alternating-current power supply 13 and the moving device 7 are connected to and controlled by a controller 14. Hence, the controller 14 controls the heating and temperature of the solution 6 and the carrying in and out of the seed crystal 3 in conjugation with each other in the crystal producing apparatus 1. The controller 14 includes a central processing unit and a storage device, such as a memory device, and is, for example, a known computer.

### Method for Producing Crystal

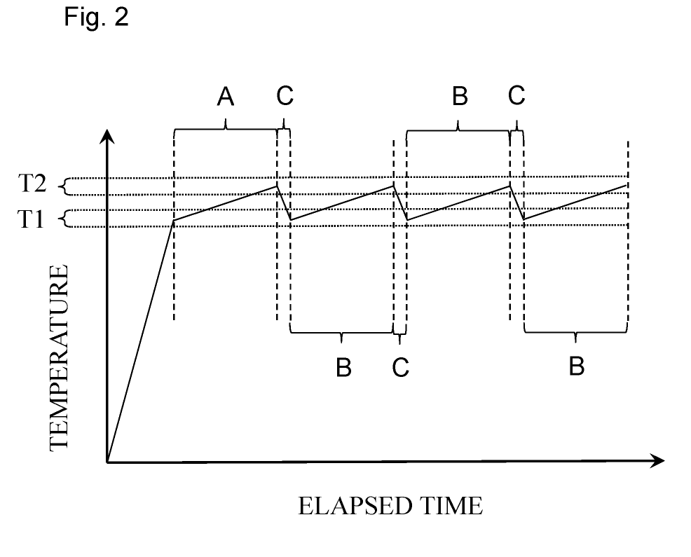

The method of the present disclosure for producing a crystal will now be described with reference to FIG. 2. FIG. 2 is an illustrative representation of the method of the present disclosure for producing a crystal and, more specifically, illustrates temperature changes of the solution 6 during the production of the crystal by means of a schematic graph with a horizontal axis representing elapsed time and a vertical axis representing temperature.

The crystal producing method mainly includes a preparation step, a contact step, a start step, a first growth step, a cooling step, a second growth step, and a removing step. The present invention is not limited to the embodiment disclosed herein, and various modifications and improvements may be made without departing from the spirit and scope of the invention.

### Preparation Step

A seed crystal 3 is prepared. The seed crystal 3 may be in a plate-like shape formed from a mass of silicon carbide crystals produced by, for example, sublimation or a solution method. In the present embodiment, a crystal 2 produced by the crystal producing method disclosed herein is used as the seed crystal 3. This enables the composition of the crystal 2 grown from the surface of the seed crystal 3 to have a composition similar to the composition of the seed crystal 3, and thus the occurrence of transition of the crystal 2 resulting from the difference in composition may be reduced. The plate-like shape can be formed by cutting a lump or mass of silicon carbide by machining.

A holding member 4 is prepared, and the seed crystal 3 is fixed to the lower surface of the holding member 4. More specifically, after preparing the holding member 4, an adhesive is applied to the lower surface of the holding member 4. Subsequently, the seed crystal 3 is placed on the lower surface of the holding member 4 with the adhesive in between, and thus fixed to the lower surface of the holding member 4. In the present embodiment, after fixing the seed crystal 3 to the holding member 4, the upper end of the holding member 4 is fixed to the moving device 7. As described above, the holding member 4 is fixed to the moving device 7 and rotatable on the axis extending in a vertical direction through the center of the holding member 4.

A crucible 5 and a solution 6 in the crucible 5 are prepared. More specifically, the crucible 5 is first prepared. Then, silicon particles, or raw material of silicon, are placed in the crucible 5, and the crucible 5 is heated to the melting point of silicon (1420° C.) or higher. The carbon (solute) of the crucible 5 is dissolved in the melted liquid silicon (solvent). Consequently, the solution 6 of carbon dissolved in the silicon solvent is prepared in the crucible 5. Alternatively, the solution 6 containing carbon may be prepared by adding carbon particles to silicon particles in advance and dissolving the carbon particles simultaneously with melting the silicon particles.

The crucible 5 is placed in the chamber 10. In the present embodiment, the crucible 5 is disposed within the crucible container 8 with a heat insulation material 9 in between. The crucible container is disposed in the chamber 10 surrounded by the coil 12 of the heating device 11. The solution 6 may be prepared by placing the crucible 5 in the chamber 10, and then heating the crucible 5 with the heating device 11.

### Contact Step

The lower surface of the seed crystal 3 is brought into contact with the solution 6. The holding member 4 is moved downward, and thus the lower surface of the seed crystal 3 is brought into contact with the solution 6. While the seed crystal 3 is brought into contact with the solution 6 by moving the seed crystal 3 downward in the present embodiment, in another embodiment, the crucible 5 may be moved upward to bring the lower surface of the seed crystal 3 into contact with the solution 6.

At least the lower surface of the seed crystal 3 is in contact with the surface of the solution 6. The seed crystal 3 may be immersed in the solution 6 such that the sides and the upper surface of the seed crystal 3, in addition to the lower surface, may come into contact with the solution 6.

### Start Step

The solution 6 is heated to a temperature in a predetermined first temperature range T1 to start growing the crystal 2 of silicon carbide from the lower surface of the seed crystal 3. The first temperature range T1 is set in a range of temperatures at which the silicon solvent is liquid. For example, the first temperature range T1 may be from 1500° C. to 2070° C.

The temperature of the solution 6 may be directly measured with, for example, a thermocouple or may be indirectly measured with a radiation thermometer. If the temperature of the solution 6 varies, the temperature may be measured a plurality of times in a specific period, and the average of the measured temperatures may be used as the temperature of the solution 6.

The seed crystal 3 may be brought into contact with the solution 6 after the solution 6 has been heated to a temperature in the first temperature range T1. By bringing the seed crystal 3 into contact after heating the solution 6, the dissolution of the seed crystal 3 can be reduced, and the production efficiency of the crystal 2 can be increased.

Alternatively, the seed crystal 3 may be brought into contact with the solution 6 before the solution 6 is heated to a temperature in the first temperature range T1. The solution 6 can dissolve the surface of the seed crystal 3 to detach foreign matter from the surface of the seed crystal 3. As a result, the quality of the crystal 2 grown from the surface of the seed crystal 3 can be improved.

### First Growth Step

The crystal 2 is precipitated from the solution 6 and grown from the lower surface of the seed crystal 3 in contact with the solution 6. When the crystal 2 is grown, first, a difference in temperature occurs between the surface of the seed crystal 3 and the solution 6 near the surface of the seed crystal 3. If the difference in temperature between the seed crystal 3 and the solution 6 causes the carbon dissolved in the solution 6 to supersaturate the solution 6, the carbon and the silicon in the solution 6 precipitate as the crystal 2 of silicon carbide on the lower surface of the seed crystal 3, and the crystal 2 is grown. The crystal 2 is grown at least from the lower surface of the seed crystal 3, and may be grown from the lower surface and the side surfaces of the seed crystal 3.

The crystal 2 can be grown in a plate-like shape or a columnar shape by pulling up the seed crystal 3. The crystal 2 can be grown with the width or the diameter of the crystal 2 kept at a predetermined value by gradually pulling the seed crystal 3 upward while adjusting the growth rate in the horizontal direction and downward direction of the crystal 2. The seed crystal 3 may be pulled at a rate, for example, in the range of 50 μm/h to 2000 μm/h. The time period for growing the crystal 2 in the first growth step may be, for example, in the range of 10 hours to 150 hours.

The seed crystal 3 is pulled up while the solution 6 is heated to a temperature in a predetermined second temperature range T2 from the temperature in the first temperature range T1, as illustrated in FIG. 2.

In some known methods for producing a crystal of silicon carbide, the growing surface changes gradually in shape as the crystal is grown. In these methods, the solution is kept at a constant temperature. In the crystal producing method disclosed herein, on the other hand, the degree of supersaturation of carbon in the solution 6 can be reduced by growing the crystal 2 while heating the solution 6. Consequently, the precipitation rate of the crystal 2 from the solution 6 is reduced, and accordingly, the change in shape of the growing surface of the crystal 2 is reduced. Thus, the quality of the crystal 2 can be improved. In FIG. 2, the first growth step is denoted by “A”; the second (and subsequent) growth steps are denoted by “B”; and the cooling steps are denoted by “C”.

The temperatures in the second temperature range T2 are higher than those in the first temperature range T1. The second temperature range T2 is set in a range of temperatures at which the silicon solvent is liquid. For example, the second temperature range T2 may be from 1700° C. to 2100° C. For example, the amount of temperature increase of the solution 6 from the first temperature range T1 to the second temperature range T2 may be, for example, in the range of 30° C. to 200° C. The time period for increasing the temperature of the solution 6 may be, for example, in the range of 10 hours to 150 hours.

The gradient of temperature changes of the solution 6 may be constant with time. In other words, the solution 6 may be monotonically heated. By monotonically heating the solution 6, the temperature of the solution 6 can be controlled efficiently, and accordingly, work efficiency can be increased. The temperature of the solution 6 may be changed at a rate, for example, in the range of 1° C./h to 15° C./h.

The solution 6 may be heated so that the degree of the supersaturation of carbon in the solution 6 can be constant. Consequently, the quality of the crystal 2 can be maintained, and the quality degradation of the crystal 2 can be reduced. As the temperature of the solution 6 is increased, the saturation concentration of carbon in the solution 6 tends to increase and the degree of the supersaturation of carbon in the solution 6 tends to decrease. In contrast, as the temperature of the solution 6 is reduced, the saturation concentration of carbon in the solution 6 tends to decrease and the degree of the supersaturation of carbon tends to increase. Accordingly, to control the degree of the supersaturation of carbon in the solution 6 to be constant, the amount of temperature increase of the solution 6 is increased in the direction from the first temperature range T1 to the second temperature range T2.

In the first growth step, the crystal 2 may be grown in the solution 6 with the lower surface of the seed crystal 3 or the lower surface of the crystal 2 kept under the surface of the solution 6. If the crystal 2 is grown in the solution 6, the difference in temperature between the crystal 2 and the solution 6 is reduced, and thus, the quality degradation of the crystal 2 can be reduced.

The solution 6 may be heated keeping the temperature of the lower portion of the solution 6 higher than the temperature of the upper portion of the solution 6. For example, the solution 6 may be heated so that the bottom temperature of the crucible 5 becomes higher than the wall temperature of the crucible 5. Thus, the heated lower portion of the solution 6 is raised by thermal convection and interchanged with the upper portion of the solution 6 having a lower temperature than the lower portion. Consequently, carbon, for example, dissolved from the crucible 5, is supplied to the growing crystal 2 effectively, and thus, the growth rate of the crystal 2 is increased.

The bottom temperature of the crucible 5 can be made higher than the wall temperature of the crucible 5 by locating the crucible 5 above the coil 12 of the heating device 11. Alternatively, the bottom temperature of the crucible 5 may be made higher than the wall temperature of the crucible 5 by moving the heat insulation material 9 between the crucible 5 and the crucible container 8. Alternatively, the temperature of the upper portion of the solution 6 may be reduced by cooling the holding member 4 so as to increase the quantity of heat transferred from the seed crystal 3 to the holding member 4.

The solution 6 may be heated keeping the temperature of the upper portion of the solution 6 higher than the temperature of the lower portion of the solution 6. By heating the solution 6 in such a manner, the degree of supersaturation of carbon in the solution 6 can be kept from being excessively increased in the vicinity of the growing crystal 2. Thus, the change in shape of the growing surface of the crystal 2 can be reduced.

The solution 6 may be heated keeping the temperature distribution in the solution 6 uniform. Consequently, the temperature gradient of the inside of the solution 6 is reduced. Thus, the degree of supersaturation of carbon can be uniformized efficiently, and the change in shape of the growing surface of the crystal 2 is reduced. In the present embodiment, uniform temperature of the inside of the solution 6 refers to, for example, a state in which the difference between the highest temperature and the lowest temperature of the inside of the solution 6 is within 10° C. Also, a uniform temperature distribution can be given efficiently to the solution 6 by adjusting the amount of heat transferred upward and the amount of heat transferred downward in the crucible 5. The amount of heat transferred upward and downward in the crucible 5 can be adjusted by, for example, adjusting the temperature of the holding member 4 and the support shaft (not shown).

In the first growth step, the crystal 2 may be rotated. By rotating the crystal 2, a flow of the solution 6 occurs in the crucible 5, and thus the range of the temperature distribution within the solution 6 can be reduced.

In the first growth step, the crucible 5 may be rotated. By rotating the crucible 5, a flow of the solution 6 occurs in the crucible 5, and thus the range of the temperature distribution within the solution 6 can be reduced.

### Cooling Step

The solution 6 is cooled from the temperature in the second temperature range T2 to a temperature in the first temperature range T1, as illustrated in FIG. 2. Thus, the second growth step, which will be described later, is made possible for increasing the length of the crystal 2.

In the present embodiment, the solution 6 may be cooled by, for example, reducing the power of the heating device 11 from the power at the end of the first growth step. The time period for cooling the solution 6 may be, for example, in the range of 0.5 hour to 3 hours. In the cooling step, the temperature of the solution 6 may be changed at a rate, for example, in the range of 10° C./h to 600° C./h.

The cooling step may be performed in a shorter period than each of the first growth step and the below-described second growth step. More specifically, the time period for cooling the solution 6, from the temperature in the second temperature range T2 to a temperature in the first temperature range T1 in the cooling step may be shorter than the time period for heating the solution 6 from a temperature in the first temperature range T1 to a temperature in the second temperature range T2 in each of the first growth step and the second growth step. Consequently, the entire time period for producing the crystal 2 is reduced, and the production efficiency can be increased.

Alternatively, the cooling step may be performed in a longer period than each of the first growth step and the second growth step. Thus, the occurrence of polycrystals in the crucible 5 can be reduced.

The crystal 2 may be detached from the solution 6 between the first growth step and the cooling step and then brought into contact with the solution 6 before the second growth step that will be described later. By cooling the solution 6 with the crystal 2 temporally detached from the solution 6, the degradation in quality of the crystal 2 resulting from, for example, an excessive increase of the degree of supersaturation of carbon in the solution 6 can be reduced.

The crystal 2 may be detached from the solution 6 while the crystal 2 being rotated together with the seed crystal 3 by the holding member 4. Thus, the solution 6 is hindered from remaining on the surface of the crystal 2. This can reduce the occurrence of defects, such as cracks, in the crystal 2, which may be caused by, for example, solidification of the solution 6.

The cooling step may be performed with the crystal 2 in contact with the solution 6. The crystal 2 may be rotated. Thus, the solution 6 can be stirred while being cooled. The rotation of the crystal 2 causes the solution 6 to flow, and therefore the range of the temperature distribution can be reduced inside of the solution 6.

The temperature of the solution 6 in the first temperature range T1 in the cooling step may be lower than the temperature in the start step or the temperature in the first temperature range T1 in the first growth step. Thus, the components of the crystal producing apparatus 1 other than the solution 6 and the crucible 5 can be cooled, and the crystal producing apparatus 1 is brought into a state close to the initial state. Thus, the growth conditions in the second growth step come close to those in the first growth step, and consequently, the crystal 2 is easily grown.

The temperature of the solution 6 in the first temperature range T1 in the cooling step may be higher than the temperature in the start step or the temperature in the first temperature range T1 in the first growth step. With this, the growth rate of the crystal 2 can be controlled efficiently to be constant even if, for example, the second growth step is repeated.

A silicon raw material may be added to the solution 6 in the cooling step. Thus, rapid increase in the degree of the supersaturation of carbon in the solution 6 can be reduced.

The silicon raw material added to the solution 6 may be powder. Silicon raw material powder is easy to dissolve in the solution 6 when added.

Alternatively, the silicon raw material added to the solution 6 may be in a lump or a mass form. The silicon raw material in a lump or a mass is unlikely to fly even by gas convection or the like in the chamber 10 because such a silicon raw material is heavier than, for example, powdery silicon. Consequently, the raw material is efficiently added.

If the silicon raw material is added to the solution 6, the cooling of the solution 6 may be started after adding the silicon raw material. Consequently, a sufficient time is secured before starting growth and the composition of the solution 6 can be stabilized. Thus, the quality of the crystal 2 that will be grown can be maintained efficiently.

The gradient of temperature changes of the solution 6 may be constant with time. In other words, the solution 6 may be monotonically cooled. By monotonically cooling the solution 6, the temperature of the solution 6 can be controlled efficiently, and accordingly, work efficiency can be increased. In such monotonically cooling, the temperature of the solution 6 may be changed at a rate, for example, in the range of 50° C./h to 500° C./h.

The solution 6 may be cooled keeping the temperature of the upper portion of the solution 6 higher than the temperature of the lower portion of the solution 6. For example, the solution 6 may be cooled keeping the wall temperature of the crucible 5 higher than the bottom temperature of the crucible 5. This can cause polycrystals to stick to the bottom of the crucible 5, thus hindering the crystal 2 from taking in polycrystals.

The solution 6 may be cooled keeping the temperature distribution in the solution 6 uniform. Consequently, the temperature gradient of the inside of the solution 6 is reduced. Thus, the degree of supersaturation of carbon in the solution 6 can be uniformized efficiently, and, for example, the occurrence of polycrystals on the inner surface of the crucible 5 can be reduced. In the present embodiment, uniform temperature of the inside of the solution 6 refers to a state in which the difference between the highest temperature and the lowest temperature in the solution 6 is, for example, within 10° C.

### Second Growth Step

After the cooling step, the crystal 2 is allowed to continue to grow by pulling up the seed crystal 3 while the solution 6 is cooled to a temperature in the second temperature range T2 from a temperature in the first temperature range T1, as illustrated in FIG. 2. Thus, the length of the crystal 2 can be increased.

In the second growth step, the seed crystal 3 may be pulled at a rate, for example, in the range of 50 μm/h to 2000 μm/h. The time period for growing the crystal 2 may be, for example, in the range of 10 hours to 150 hours. For example, the temperature of the solution 6 may be set in the range of 1500° C. to 2100° C.

### Removing Step

After the second growth step, the grown crystal 2 is detached from the solution 6 to complete crystal growth.

The present invention is not limited to the embodiments and forms described above, and various modifications and improvements may be made without departing from the spirit and scope of the invention.

In the present invention, the cooling step and the second growth step may each be repeated a plurality of times. By repeating the cooling step and the second growth step, degradation in quality of the crystal 2 can be reduced, and a crystal 2 having a desired length can be produced. The cooling step and the second growth step may be repeated, for example, 40 times to 100 times.

The time period for the second growth step may be reduced with increasing times of repetition of the step. In general, if a crystal 2 is grown for a long time, the crystal 2 becomes thick and long, consequently becoming difficult to grow because heat dissipation from the lower surface of the crystal 2 is reduced. On the other hand, if the time period of the second growth step is reduced, the degree of supersaturation of carbon in the solution 6 is increased, and the growth rate of the crystal 2 can be maintained efficiently.

The temperature of the solution 6 in the cooling step may be reduced with increasing times of repetition of the step. Thus, thermal load on the grown crystal 2 can be reduced.

Another step may be added between the cooling step and the second growth step for maintaining the temperature of the solution. This helps stabilize the composition of the solution 6 before the second growth step, or stabilize the temperature of the components of the crystal producing apparatus 1, thus improving the quality of the crystal 2.

### REFERENCE SIGNS LIST

1 crystal producing apparatus

2 crystal

3 seed crystal

4 holding member

5 crucible

6 solution

7 moving device

8 crucible container

9 heat insulation material

10 chamber

101 through hole

102 gas supply port

103 exhaust port

11 heating device

12 coil

13 alternating-current power supply

14 controller

T1 first temperature range

T2 second temperature range

A first growth step

B second growth step

C cooling step

1. A method for producing a crystal of silicon carbide, the method comprising:
a preparation step of preparing a solution in which carbon is dissolved in a silicon solvent, and preparing a seed crystal of silicon carbide;
a contact step of bringing a lower surface of the seed crystal into contact with the solution;
a start step of starting to grow a crystal from the lower surface of the seed crystal by heating the solution to a temperature in a first temperature range;
a first growth step of growing the crystal after the start step by pulling up the seed crystal upward while the solution is heated from the temperature in the first temperature range to a temperature in a second temperature range;
a cooling step of cooling the solution from the temperature in the second temperature range to any one of the temperatures in the first temperature range; and
a second growth step of further growing the crystal after the cooling step by pulling up the seed crystal upward while the solution is heated from the temperature in the first temperature range to any one of the temperatures in the second temperature range.

2. The method according to claim 1, wherein
the cooling step and the second growth step are each repeated.

3. The method according to claim 1, wherein
the crystal is detached from the solution in the cooling step.

4. The method according to claim 1, wherein
the solution is cooled in the cooling step keeping the crystal in contact with the solution.

5. The method according to claim 1, wherein
a silicon raw material is added to the solution in the cooling step.

6. The method according to claim 1, wherein
the solution is heated in the first growth step to a temperature in the second temperature range from a temperature in the first temperature range keeping a degree of supersaturation of carbon in the solution constant.

7. The method according to claim 2, wherein
the crystal is detached from the solution in the cooling step.

8. The method according to claim 2, wherein
the solution is cooled in the cooling step keeping the crystal in contact with the solution.

9. The method according to claim 2, wherein
a silicon raw material is added to the solution in the cooling step.

10. The method according to claim 3, wherein
a silicon raw material is added to the solution in the cooling step.

11. The method according to claim 4, wherein
a silicon raw material is added to the solution in the cooling step.

12. The method according to claim 7, wherein
a silicon raw material is added to the solution in the cooling step.

13. The method according to claim 8, wherein
a silicon raw material is added to the solution in the cooling step.

14. The method according to claim 2, wherein
the solution is heated in the first growth step to a temperature in the second temperature range from a temperature in the first temperature range keeping a degree of supersaturation of carbon in the solution constant.

15. The method according to claim 3, wherein
the solution is heated in the first growth step to a temperature in the second temperature range from a temperature in the first temperature range keeping a degree of supersaturation of carbon in the solution constant.

16. The method according to claim 4, wherein
the solution is heated in the first growth step to a temperature in the second temperature range from a temperature in the first temperature range keeping a degree of supersaturation of carbon in the solution constant.

17. The method according to claim 5, wherein
the solution is heated in the first growth step to a temperature in the second temperature range from a temperature in the first temperature range keeping a degree of supersaturation of carbon in the solution constant.
